(19) United States
(12) Patent Application Publication
(10) Pub. No.: US 2024/0316581 A1
(43) Pub. Date: Sep. 26, 2024

(54) BUFFER TANK, SUPPLY BLOCK INCLUDING BUFFER TANK, AND GAS SUPPLY DEVICE

(71) Applicant: JUSUNG ENGINEERING CO., LTD., Gwangju-Si, Gyeonggi-Do (KR)

(72) Inventors: Ji Hun LEE, Gwangju-Si, Gyeonggi-Do (KR); Dae Soo JANG, Gwangju-Si, Gyeonggi-Do (KR)

(21) Appl. No.: 18/578,813

(22) PCT Filed: Jul. 26, 2022
(86) PCT No.: PCT/KR2022/010987

§ 371 Date: Jan. 12, 2024

(30) Foreign Application Priority Data
Aug. 3, 2021 (KR) 10-2021-0101956
Jul. 22, 2022 (KR) 10-2022-0090981

(51) Int. Cl. B05B 7/14; B05B 7/16; B05B 15/40

(52) U.S. Cl. CPC B05B 7/1404; B05B 7/16; B05B 15/40

(57) ABSTRACT

In accordance with an exemplary embodiment, a buffer tank that supplies a gas into a chamber in which a substrate is processed includes: a first body having, therein, a first space accommodating a gas; a second body having a second space having a volume less than that of the first space and accommodating a gas and installed in the first space; and a filter installed in the second body so as to be disposed in the second space. In accordance with exemplary embodiments, a gas supplied from a gas supply unit may remain in the buffer tank for a predetermined time, and inner pressure of the buffer tank may increase. Thus, pressure of the gas discharged from the buffer tank may increase, and accordingly, injection pressure of the gas injected into the chamber connected with the buffer tank may increase.

### TECHNICAL FIELD

The present disclosure relates to a buffer tank and a supply block including the buffer tank, and more particularly, to a buffer tank allowing pressure of a gas supplied into a chamber to increase, a supply block including the buffer tank, and a gas supply device.

### BACKGROUND ART

A substrate processing apparatus that deposits a thin-film on a substrate includes a chamber, a support installed in the chamber to support the substrate, and an injection unit installed in the chamber to inject a gas toward the support.

The injection unit is connected with a transfer pipe installed at the outside of the chamber and a storage part in which a gas for a substrate processing process is stored. Thus, the gas of the storage part is introduced to the injection unit through the transfer pipe and then injected into the chamber through the injection unit.

The storage part is spaced apart from the chamber, and thus the transfer pipe has a long extension length. Thus, when the gas of the storage part is injected from the injection unit through the transfer pipe, the gas has low injection pressure.

Also, in case of an atomic layer deposition, a purge gas is injected into the chamber to purge unreacted gases or by-products after a source gas or a reactant gas is injected. However, since the purge gas discharged from the storage part spaced apart from the chamber passes through the transfer pipe and then is injected from the injection unit, the purge gas has low injection pressure. Thus, a purge efficiency of the purge gas is degraded.
(related patent document 1) Korean Registration No. 0458140

### SUMMARY

The present disclosure provides a buffer tank capable of allowing pressure of a gas supplied into a chamber to increase, a supply block including the buffer tank, and a gas supply device.

The present disclosure also provides a buffer tank capable of preventing or suppressing impurities from being supplied into a chamber, a supply block including the buffer tank, and a gas supply device.

In accordance with an exemplary embodiment, a buffer tank that supplies a gas into a chamber in which a substrate is processed includes: a first body having, therein, a first space accommodating a gas; a second body having a second space having a volume less than that of the first space and accommodating a gas and installed in the first space; and a filter installed in the second body so as to be disposed in the second space.

A heater may be installed in the first body so as to be disposed in the first space.

The buffer tank may further include a valve installed between the second space and the chamber.

In accordance with another exemplary embodiment, a supply block that supplies a gas into a chamber in which a substrate is processed includes: a buffer tank having a first space accommodating a gas and a second space having a volume less than that of the first space and separated from the first space and including a filter installed in the second space; and a gas block having a first flow path connected with the second space and a second flow path connected with the inside of the chamber and disposed at one side of the buffer tank.

The supply block may further include a valve connected to the gas block to control communication between the first flow path and the second flow path.

The supply block may further include a heater installed in the buffer tank so as to be disposed in the first space.

In accordance with yet another exemplary embodiment, a gas supply device that supplies a gas into a chamber in which a substrate is processed includes: a base having a flow path communicating with the inside of the chamber and installed on the chamber; and a buffer tank having an inner space accommodating a gas and installed on the base to supply a gas to the flow path. Here, the inner space has a first space and a second space having a volume less than that of the first space and separated from the first space, and the buffer tank includes a filter disposed in the second space.

The buffer tank may include: a first body having a first space therein; a second body having, therein, a second space having a volume less than that of the first space and disposed in the first space; and a valve installed between the second space and the chamber.

The buffer tank may include: a first body having a first space therein; a second body having, therein, a second space having a volume less than that of the first space and disposed in the first space; and a discharge pipe connected with the second space. Here, the gas supply device may further include a gas block having a first flow path connected with the discharge pipe and a second flow path connected with the flow path of the base and installed on the base.

The gas supply device may further include a valve installed on the gas block to control communication between the first flow path and the second flow path.

In accordance with still another exemplary embodiment, a buffer tank that supplies a gas into a chamber in which a substrate is processed includes a first body having, therein, a first space accommodating a gas, and a heater is installed in the first space.

The buffer tank may further include: a second body having a second space having a volume less than that of the first space and installed in the first space; and a filter installed in the second body so as to be disposed in the second space.

A gas block having a first flow path communicating with the second space and a second flow path communicating with the inside of the chamber may be connected to the first body.

The first body may be installed on the second space and a base having a flow path communicating with the inside of the chamber and installed on the chamber.

The buffer tank may further include a cover having one surface connected with the heater, installed on the first body to close an opening of the first body, and having a flow path communicating with the first space therein.

The buffer tank may further include a counter-pressure prevention part installed on the heater to surround the heater in a circumferential direction of the heater. Here, the first space, which communicates with an inlet through which a gas is introduced, may have one side space disposed at one side of the counter-pressure prevention part and the other side space spaced apart relatively to the one side space from the inlet and disposed at the other side of the counter-pressure prevention part.

The other side space may have a volume greater than that of the one side space.

In accordance with yet still another exemplary embodiment, a gas supply device that supplies a gas into a chamber in which a substrate is processed includes: a base having a flow path communicating with the inside of the chamber and installed on the chamber; a buffer tank having an inner space accommodating a gas and installed on the base to supply a gas to the flow path; and a filter connected between the base and the buffer tank.

In accordance with the exemplary embodiments, the gas supplied from the gas supply unit may remain in the buffer tank for a predetermined time, and the inner pressure of the buffer tank may increase. Thus, the pressure of the gas discharged from the buffer tank may increase, and accordingly, the injection pressure of the gas injected into the chamber connected with the buffer tank may increase.

Here, when the gas injected into the chamber is the purge gas, the purge efficiency using the purge gas may increase. Also, when the gas injected into the chamber is the source material of the thin-film to be deposited, the amount of the gas arrived at the substrate may increase, and the thin-film deposition efficiency may increase.

Also, as the filter is disposed in the buffer tank through which the gas passes, the filter may prevent or suppress the impurities from being mixed in the gas injected into the chamber. Thus, the substrate or the thin-film may be prevented from being polluted by the impurities.

### BRIEF DESCRIPTION OF THE DRAWINGS

Exemplary embodiments can be understood in more detail from the following description taken in conjunction with the accompanying drawings, in which:

FIG. 1 is a view illustrating a substrate processing apparatus including a gas supply device in accordance with an exemplary embodiment;

FIG. 2 is a view illustrating a substrate processing apparatus including a gas supply device in accordance with another exemplary embodiment;

FIGS. 3 and 4 are views for explaining a flow of a gas according to an operation of a valve of the gas supply device in accordance with another exemplary embodiment;

FIG. 5 is a view illustrating a gas supply device in accordance with yet another exemplary embodiment; and

FIG. 6 is a view illustrating a gas supply device in accordance with still another exemplary embodiment.

### DETAILED DESCRIPTION OF EXEMPLARY EMBODIMENTS

Hereinafter, specific embodiments will be described in more detail with reference to the accompanying drawings. The present invention may, however, be embodied in different forms and should not be construed as limited to the embodiments set forth herein. Rather, these embodiments are provided so that this disclosure will be thorough and complete, and will fully convey the scope of the present invention to those skilled in the art. In the figures, the dimensions of layers and regions are exaggerated for clarity of illustration. Like reference numerals refer to like elements throughout.

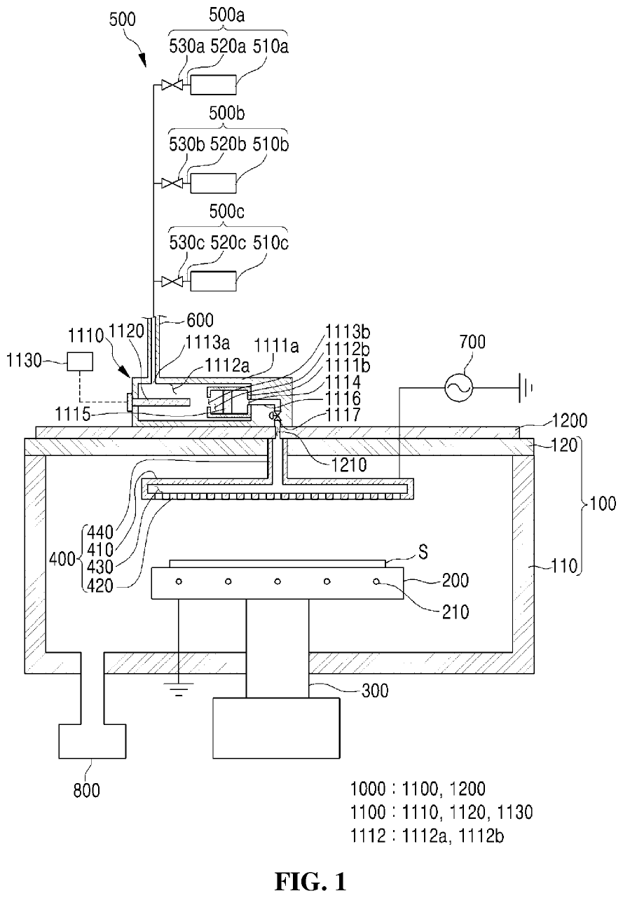

FIG. 1 is a view illustrating a substrate processing apparatus including a gas supply device in accordance with an exemplary embodiment.

Referring to FIG. 1, the substrate processing apparatus may include: a chamber 100 having an inner space in which a substrate S is processed; a support 200 supporting the substrate S loaded into the chamber 100; an injection unit 400 disposed in the chamber 100 to face the support 200 and injecting a gas; and a gas supply device 1000 supplying a gas to the injection unit 400 so that pressure injected from the injection unit 400 increases and installed at the outside of the chamber 100.

Also, the substrate processing apparatus may include: a gas supply unit 500 storing a gas injected into the chamber 100 and connected to the gas supply device 1000; a connection pipe 600 connecting the gas supply unit 500 with the gas supply device 1000; a RF power unit 700 applying a power to the injection unit 400 so as to generate plasma in the chamber 100; a driving unit 300 operating the support 200 to perform at least one of elevation or rotation; and an exhaust unit 800 connected to the chamber 100 so as to exhaust at least one of a gas and a by-product in the chamber 100.

The chamber 100 has an inner space in which the substrate S is processed and keeps the inner space airtight. For example, the chamber 100 may include a body 110 having the inner space and a lid 120 that covers an upper opening of the body 110.

The support 200 is disposed in the chamber 100 to face the injection unit 400 and support the substrate S loaded into the chamber 100. The support 200 may be manufactured with a size greater than that of the substrate S and have, e.g., a rectangular shape corresponding to the substrate S. Also, the support 200 may be grounded. Also, a heater 210 may be disposed in the support 200. Thus, when the heater 210 is operated, the substrate S seated on the support 200 and the inside of the chamber 100 may be heated.

The injection unit 400 is disposed in the chamber 100 to face the support 200 and injects a gas toward the support 200. Here, the injection unit 400 receives a gas from the gas supply device 1000 that will be described later and injects the received gas into the chamber 100.

For example, the injection unit 400 may have a shower head shape having a plurality of injection holes 420. That is, the injection unit 400 may include an injection body 410 extending in an extension direction of the support 200 and having an inner space 430 for accommodating a gas and a plurality of injection holes 420 defined at a lower portion of the injection body 410 to face the support 200 and arranged and spaced apart from each other in the extension direction of the support 200. Also, the injection unit 400 may include a supply pipe 440 having an inner passage communicating with the inner space 430 of the injection body 410 and connecting the injection body 410 with the gas supply device 1000. Each of the plurality of injection holes 420 is defined in the lower portion of the injection body 410 to communicate with the inner space 430 at a lower side of the inner space 430. Accordingly, a gas introduced into the inner space 430 of the injection body 410 through the supply pipe 440 is injected into the chamber 100 through the plurality of injection holes 420.

However, the exemplary embodiment is not limited to the above-described configuration and shape of the injection unit 400. For example, the injection unit 400 may have all sorts of configurations and shapes as long as the injection unit 400 may inject a gas into the chamber 100 or toward the support 200.

The gas supply unit 500 is connected with the gas supply device 1000 to provide or supply a gas to the gas supply device 1000. Also, when a plurality kinds of gases are injected into the chamber 100 for processing a substrate, the gas supply unit 500 may be provided in plurality. As a more specific example, when the substrate processing apparatus deposits a thin-film on the substrate S by using an atomic layer deposition (ALD) method, the gas supply unit 500 may include a first gas supply part 500a supplying a source gas, a second gas supply part 500b supplying a reactant gas, and a third gas supply part 500c supplying a purge gas.

Also, the first to third gas supply parts 500a, 500b, and 500c may include, respectively, gas storage parts 510a, 510b, and 510c, transfer parts 520a, 520b, and 520c connecting the gas storage parts 510a, 510b, and 510c with the gas supply device 1000, and valves 530a, 530b, and 530c installed on the transfer parts 520a, 520b, and 520c, respectively, to control communication between the gas storage parts 510a, 510b, and 510c and the gas supply device 1000. Here, the source gas may be stored in the first gas storage part 510a, the reactant gas may be stored in the second gas storage part 510b, and the purge gas may be stored in the third gas storage part 510c.

The feature in which the gas supply unit 500 includes three gas supply parts 500a, 500b, and 500c is described above. However, the gas supply unit 500 may include three or less gas supply parts. Also, the gas supplied from the gas supply unit may include various gases injected into the chamber 100 instead of being limited to the source gas, the reactant gas, and the purge gas used for atomic layer deposition.

The gas supply device 1000 supplies a gas to the injection unit 400 so that the pressure injected from the injection unit 400 increases. That is, the gas supply device 1000 allows the injection pressure injected from the injection unit 400 into the chamber 100 to increase in comparison with a case when the gas of the gas supply unit 500 is directly supplied to the injection unit 400.

The gas supply device 1000 that is a unit for supplying a gas to the injection unit 400 may be installed outside the chamber 100. More specifically, as illustrated in FIG. 1, the gas supply device 1000 may be mounted to an upper portion of the lid 1120 of the chamber 100. However, the exemplary embodiment is not limited to the installation position of the gas supply device 1000. For example, the gas supply device 1000 may be installed at any position as long as the gas supply device 1000 is connected to the injection unit 400 from the outside of the chamber 100.

The gas supply device 1000 may include a supply block 1100 including a buffer tank 1110 having an inner space for temporarily accommodating a gas supplied from the gas supply unit 500 and a base 1200 disposed on the chamber 100 to couple or separate the supply block 1100, so that pressure of a gas moved or discharged to the injection unit 400 increases.

The supply block 1100 may include the buffer tank 1110 having an inner space 1112 capable of accommodating a gas and including a filter 1115 capable of filtering impurities. Also, the supply block 1100 may further include a heater 1120 disposed in the buffer tank 1110 to heat a gas therein. Also, the supply block 1100 may include a pressure measurement part (not shown) for measuring inner pressure of the buffer tank 1110, and the pressure measurement part may be installed, for example, on the heater 1120.

The buffer tank 1110 is a unit for temporarily storing a gas supplied from the gas supply unit 500 and supplying a high pressure gas into the chamber 100 or to the injection unit 400. The buffer tank 1110 has the inner space 1112, and the inner space 1112 includes a first space 1112a and a second space 1112b separated from the first space 1112a. Here, the first space 1112a may have a volume greater than that of the second space 1112b, and the filter 1115 may be installed in the second space 1112b.

More specifically, the buffer tank 1110 may include: a first body 1111a having the first space 1112a capable of accommodating a gas therein; a second body 1111b having the second space 1112b capable of accommodating a gas therein and installed in the first space 1112a of the first body 1111a; the filter 1115 installed in the second space 1112b of the second body 1111b; a discharge pipe 1116 having one end connected to the second body 1111b and the other end connected to the injection unit 400; and a valve (hereinafter, referred to as a buffer valve 1117) installed on the discharge pipe 1116 to control communication with the injection unit 400.

The first body 1111a may be a unit for forming an outermost wall of the buffer tank 1110. The first body 1111a has an inner space capable of accommodating a gas, i.e., the first space 1112a. Here, as described above, the first space 1112a may have a volume greater than that of the second space 1112b.

Also, the connection pipe 600 and a first inlet 1113a communicating with the first space 1112a are disposed on the first body 1111a. Here, the first inlet 1113a may be disposed at the outside of the second body 1111b. In other words, the second body 1111b may be disposed between the first inlet 1113a and the discharge pipe 1116 in the first space 1112a. Thus, a position of the first inlet 1113a is not in overlap with the second body 1111b and is disposed at the outside of the second body 1111b.

The second body 1111b has an inner space capable of accommodating a gas, i.e., the second space 1112b. Also, the second body 1111b is installed in the first body 1111a. Here, the feature in which the second body 1111b is installed in the first body 1111a may represent that the second body 1111b is installed to be accommodated in the first space 1112a. Here, the second body 1111b may have a volume less than that of the first space 1112a.

A second inlet 1113b that is a passage through which a gas introduced to the first space 1112a is introduced to the second space 1112b and an outlet 1114 that is a passage through which a gas of the second space 1112b is discharged to the discharge pipe 1116 are disposed on the second body 1111b. Thus, the second space 1112b may be a space between the second inlet 1113b and the outlet 1114. Also, the gas introduced to the first space 1112a of the first body 1111a through the first inlet 1113a may be introduced into the second space 1112b through the second inlet 1113b of the second body 1111b and then discharged to the outside through the outlet 1114 and the discharge pipe 1116.

The discharge pipe 1116 is a unit for discharging a gas in the buffer tank 1110 to the outside, i.e., to the injection unit 400. More specifically, the discharge pipe supplies the gas introduced into the second space 1112b of the second body 1111b to the injection unit 400. To this end, the discharge pipe 1116 has one end connected with the outlet 1114 of the second body 1111b and the other end connected with the supply pipe 440 of the injection unit 400. Here, the discharge pipe 1116 may pass through a portion of the first body 1111a as illustrated in FIG. 1. That is, the discharge pipe 1116 may pass through a portion of an area of the first body 1111a between the second body 1111b and the injection unit 400.

The buffer valve 1117 is installed on the discharge pipe 1116 to control communication between the second space 1112b and the injection unit 400. That is, the buffer valve 1117 may be installed on the discharge pipe 1116 so that the buffer valve 1117 is disposed on an extension path of the discharge pipe 1116. Here, the buffer valve 1117 may be a unit operated by a signal or force applied from the outside. Alternatively, the buffer valve 1117 may be operated by inner pressure of the buffer tank 1110, which is measured by the pressure measurement part.

The filter 1115 is disposed in the second body 1111b, i.e., the second space 1112b, to filter impurities such as solid particles and solid powder mixed in a gas. Here, for example, the filter 1115 may be a unit having a plurality of openings each having a size less than that of each of the particles to be filtered. For another example, the filter 1115 may be an electrostatic filter that absorbs particles mixed in a gas using static electricity. However, the exemplary embodiment is not limited to the above-described examples of the filter 1115. For example, the filter 1115 may include various units capable of filtering impurities mixed in a gas.

The heater 1120, as a unit for preventing a gas introduced into the buffer tank 1110 from being liquefied, heats the gas in the inner space of the buffer tank 1110. The heater 1120 is installed to be disposed in the first body 1111a. That is, the heater 1120 may be installed in the first body 1111a so that the heater 1120 is disposed in the first space 1112a. Here, the heater 1120 is disposed in the first space 1112a so that the heater 1120 is disposed at the outside of the second body 1111b or the second space 1112b.

For example, the heater 1120 may be a unit including a metal heating element that generates heat due to resistance caused by a current applied thereto. In this case, a power source 1130 for applying a current may be connected to the heater 1120 and disposed at the outside of the buffer tank 1110.

The base 1200 is a unit for supporting the supply block 1100 and allowing the supply block 1100 to be mounted to the chamber 100. That is, the base 1200 allows a plurality of components of the supply block 1100 to be easily mounted onto the chamber 100.

For example, when the supply block 1100 includes one buffer tank 1110, the base 1200 is provided so that the buffer tank 1110 is coupled and separated. Here, since the buffer tank 1110 is installed on the base 1200, a flow path 1210 through which a gas discharged from the buffer tank 1110 is transferred into the chamber 100 or the injection unit 400 is defined in the base 1200. More specifically, the flow path 1210 connected with the discharge pipe 1116 of the buffer tank 1110 is defined in the base 1200. Thus, a gas discharged from the discharge pipe 1116 of the buffer tank 1110 passes through the flow path 1210 of the base 1200 and then is injected into the chamber 100 through the injection unit 400.

Also, the supply block 1100 may include a plurality of components. For example, the supply block 1100 may include a plurality of buffer tanks 1110 or further include a component different from the buffer tank 1110. Here, for example, the component different from the buffer tank 1110 may be a unit having a space in which a gas is accommodated or through which a gas passes. Thus, a plurality of flow paths 1210 may be defined in the base 1200 to couple the plurality of buffer tanks 1110 or additionally couple the component different from the buffer tank 1110 as necessary. Here, the plurality of flow paths 1210 may be defined in different positions.

As the base 1200 has the plurality of flow paths 1210 defined in different positions, the plurality of buffer tanks 1110 may be mounted to the base 1200 or the component different from the buffer tank 1110 may be additionally mounted or assembled to the base 1200 as necessary. In other words, the plurality of buffer tanks 1110 may be easily assembled or the component different from the buffer tank 1110 may be easily additionally assembled as necessary. That is, the plurality of buffer tanks 1110 may be mounted, or the component different from the buffer tank 1110 may be additionally mounted or assembled as necessary in order to control, e.g., the kinds, flow rate, or pressure of, the gas supplied into the chamber 100.

Also, a separate coupling member for coupling or separating the supply block 1100 and the base 1200 may be used. For example, when the supply block 1100 includes one buffer tank 1110, the coupling member for coupling or separating the supply block 1100 and the base 1200 may be provided. For example, the coupling member may include a coupler having a portion inserted to the base 1200 and the first body 1111a of the buffer tank 1110 and a fixer for fixing the coupler to the first body 1111a at the outside of the first body 1111a. Here, the coupler may be a bolt in which a thread is formed on an outer circumferential surface thereof, and the fixer may be a nut in which a thread is formed on an inner circumferential surface thereof. Here, a coupling hole to which the coupler is inserted or through which the coupler passes may be defined in each of the buffer tank 1110 and the base 1200. The buffer tank 1110 may be coupled or fastened to or separated from the base 1200 by the coupling member and the coupling hole.

Also, as described above, the supply block 1100 may include the plurality of buffer tanks 1110 and may further include other components except for the buffer tank 1110. Here, each of the plurality of buffer tanks 1110 or other components except for the buffer tank 1110 may be coupled onto the base 1200 by using the coupling member. Also, a plurality of coupling holes to which a plurality of couplers are inserted, respectively, may be defined in the base 1200, and the plurality of coupling holes may be defined in different positions.

As the base 1200 has the plurality of flow paths 1210 defined in different positions, the plurality of buffer tanks 1110 may be mounted to the base 1200 or the component different from the buffer tank 1110 may be additionally mounted or assembled to the base 1200 as necessary. That is, as described above, the plurality of buffer tanks 1110 may be mounted, or the component different from the buffer tank 1110 may be additionally mounted or assembled as necessary in order to control, e.g., the kinds, flow rate, or pressure of, the gas supplied into the chamber 100.

As described above, the supply block 1100 of the gas supply device 1000 in accordance with an exemplary embodiment includes the buffer tank 1110 capable of temporarily accommodating the gas supplied from the gas supply unit 500. In other words, the gas supply device 1000 includes the buffer tank 1110 connected between the gas supply unit 500 and the injection unit 400.

The buffer tank 1110 may move the gas supplied or discharged from the gas supply unit 500 to the injection unit 400 with high pressure instead of directly moving the gas to the injection unit 400. More specifically, the buffer tank 1110 supplies the gas of the gas supply unit 500 in a closed state of the buffer valve 1117. Thus, the gas passing through the connection pipe 600 is introduced into the inner space 1112 of the buffer tank 1110. That is, the gas passing through the connection pipe 600 is introduced into the first space 1112a of the first body 1111a through the first inlet 1113a and then introduced into the second space 1112b of the second body 1111b. Also, when the gas is continuously supplied to the first space 1112a in the closed state of the buffer valve 1117, the inner space 1112 of the buffer tank 1110, i.e., the first space 1112a and the second space 1112b communicating with the first space 1112a increases in pressure.

Thereafter, when the pressure of the inner space 1112 of the buffer tank 1110 reaches to predetermined pressure or preset pressure, gas supply from the gas supply unit 500 is stopped, and the buffer valve 1117 is opened.

Here, for example, the pressure of the inner space 1112 of the buffer tank 1110 may be measured by using a pressure adjustment part installed on the heater 1120. Also, when the pressure measured by the pressure adjustment part reaches to the preset pressure, the buffer valve 1117 may be opened.

When the buffer valve 1117 is opened, the gas of the inner space 1112 of the buffer tank 1110 is supplied to the injection unit 400 through the flow path 1210 of the base 1200 and the discharge pipe 1116 and then injected into the chamber 100 through the injection unit 400. That is, the gas in the second space 1112b or the second body 1111b of the buffer tank 1110 is discharged to the outside of the buffer tank 1110 through the discharge pipe 1116, supplied to the injection unit 400 through the flow path 1210 defined in the base 1200, and then injected through the injection hole 420 of the injection unit 400. Here, since the inner space 1112 of the buffer tank 1110 has high pressure, discharge pressure of the gas of the inner space 1112 of the buffer tank 1110 through the discharge pipe 1116 is high, and injection pressure injected into the chamber 100 through the injection unit 400 is high.

Thus, the gas that is temporarily accommodated in the buffer tank 1110 and then supplied to the injection unit 400 in accordance with an exemplary embodiment may be injected into the chamber 100 with higher pressure than a case when the gas supplied from the gas supply unit 500 is directly supplied to the injection unit 400.

Here, when the gas supplied from the gas supply unit 500 is a purge gas as an example, the purge gas may be injected with high injection pressure, and thus a purge efficiency may be improved. This is because an amount of by-products or impurities purged into the chamber relatively increases in case of high injection pressure like an exemplary embodiment when an amount of the injected purge gas is equal.

For another example, when the gas supplied from the gas supply unit 500 is a source gas or a reactant gas for thin-film deposition, the source gas or the reactant gas may be injected with high injection pressure through the injection unit 400, and thus a deposition rate may be improved. Particularly, when a thin-film is deposited on a trench defined in the substrate S, the gas may be easily arrived at the inside of the trench due to the high injection pressure of the source gas or the reactant gas. Thus, when an injection amount of the source gas or the reactant gas is equal, due to the high injection pressure, an amount of the gas arrived at the trench relatively increases, so that the deposition rate increases.

Also, in an exemplary embodiment, the gas of the inner space 1112 of the buffer tank 1110 may be heated by using the heater 1120. That is, the gas in the first space 1112a and the second space 1112b may be heated. Thus, while the gas is accommodated or stored in the inner space 1112 of the buffer tank 1110 for a predetermined time, a temperature of the gas decreases to prevent the gas from being liquefied.

Also, the filter 1115 is disposed in the inner space 1112 of the buffer tank 1110. That is, the filter 1115 is disposed in the second space 1112b of the second body 1111b. Also, since the discharge pipe 1116 is connected with the second space 1112b of the second body 1111b, and the buffer valve 1117 is installed on the discharge pipe 1116, the gas of the inner space 1112 of the buffer tank 1110 is introduced into the second space 1112b of the second body 1111b and then discharged through the discharge pipe 1116. That is, the gas of the buffer tank 1110 is discharged through the second space 1112b and then discharge pipe 1116. Thus, the gas flows toward the discharge pipe 1116 to pass through the filter 1115. When the gas passes through the filter 1115, impurities mixed in the gas do not pass through the filter 1115. That is, the impurities are filtered by the filter 1115. Thus, the gas from which the impurities are filtered or removed is supplied to the injection unit 400 through the discharge pipe 1116. Thus, the impurities may be prevented or suppressed from being supplied to the injection unit 400, and a process quality of the substrate S, e.g., a quality of the thin-film, may be improved.

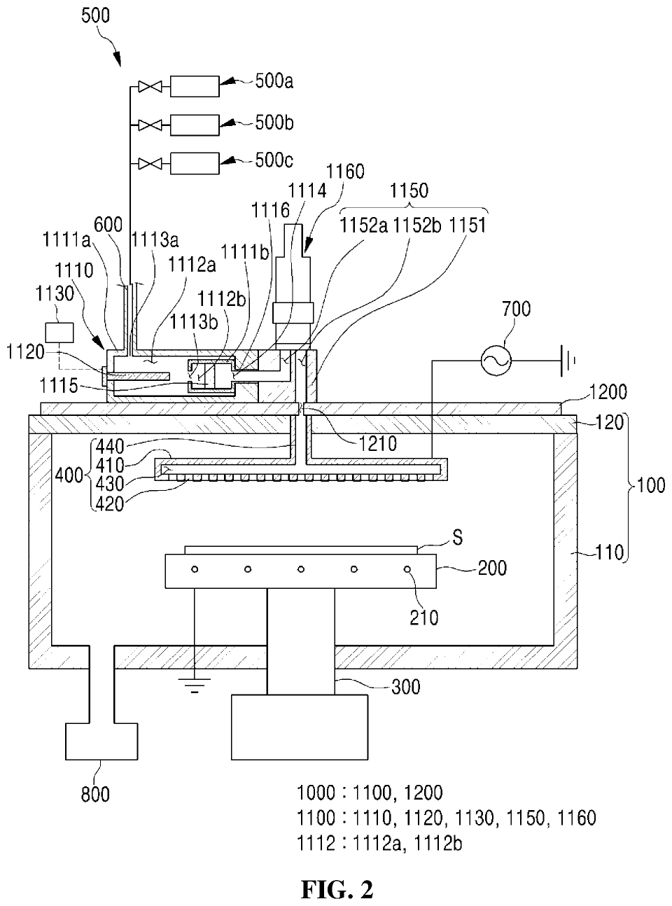

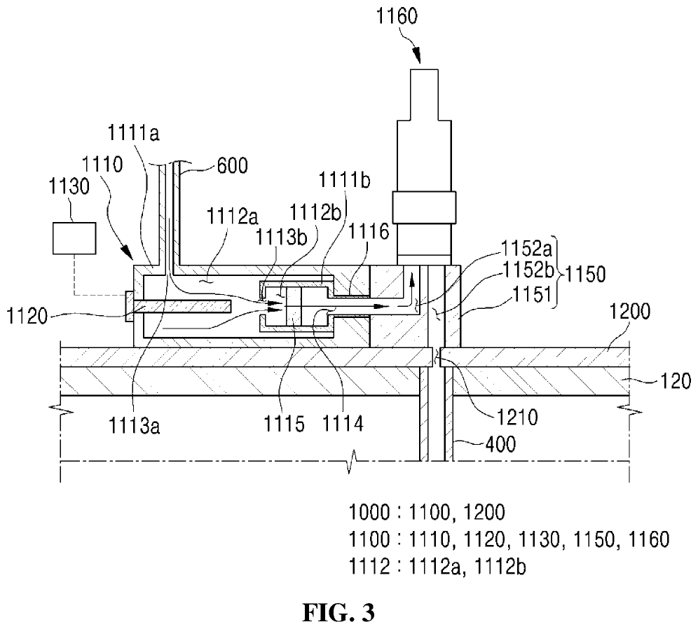

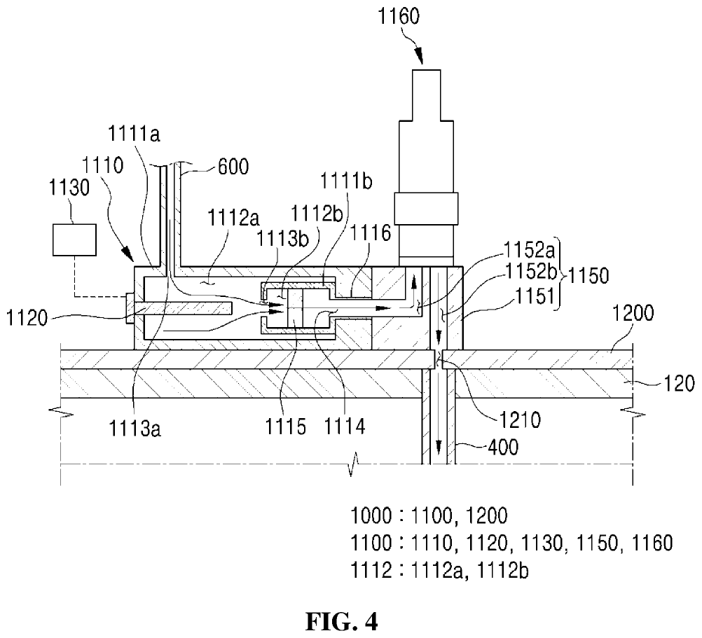

FIG. 2 is a view illustrating a substrate processing apparatus including a gas supply device in accordance with another exemplary embodiment. FIGS. 3 and 4 are views for explaining a flow of a gas according to an operation of a valve of the gas supply device in accordance with another exemplary embodiment.

In accordance with an exemplary embodiment, the supply block 1100 includes the buffer tank 1110, the buffer tank 1110 is directly connected with the injection unit 400, and the buffer valve 1117 is installed on the discharge pipe 1116. However, the exemplary embodiment is not limited thereto. For example, the supply block 1100 may further include a gas block 1150 connecting the buffer tank 1110 and the injection unit 400 as in another exemplary embodiment illustrated in FIGS. 2 to 4.

Hereinafter, a gas supply device 1000 in accordance with another exemplary embodiment will be described with reference to FIGS. 2 to 4. Hereinafter, descriptions duplicated with those of an exemplary embodiment will be omitted or simplified.

Referring to FIG. 2, a gas supply device 1000 in accordance with another exemplary embodiment may include: a buffer tank 1110 having an inner space 1112 capable of temporarily accommodating a gas and including a filter 1115 capable of filtering impurities; a gas block 1150 having a first flow path 1152a connected with the buffer tank 1110 and a second flow path 1152b connected with a flow path 1210 of a base 1200, and a valve 1160 installed on the gas block 1150 to close or open each of the first and second flow paths 1152a and 1152b. Also, the supply block 1100 may further include a heater 1120 disposed in the inner space 1112 of the buffer tank 1110 to heat a gas therein. Also, the supply block 1100 may include a pressure measurement part (not shown) for measuring inner pressure of the buffer tank 1110, and the pressure measurement part may be installed, for example, on the heater 1120.

The buffer tank 1110 has a configuration and a structure similar to those described in an exemplary embodiment. However, in the buffer tank 1110 in accordance with another exemplary embodiment, a discharge pipe 1116 is connected with the first flow path 1152a of the gas block 1150 that will be described later instead of being connected with the flow path 1210 of the base 1200.

The gas block 1150 includes a body 1151, the first flow path 1152a defined in the body 1151 to connect the buffer tank 1110 and the valve 1160, and the second flow path 1152b defined in the body 1151 to connect the valve 1160 and an injection unit 400.

For example, the body 1151 may have a hexahedral shape having a rectangular cross-sectional shape. However, the exemplary embodiment is not limited to the shape of the body 1151. For example, the body 1151 may have various shapes in which the first and second flow paths 1152a and 1152b are defined.

The first flow path 1152a is defined in the body 1151 so that the first flow path 1152a has one end connected with the discharge pipe 1116 of the buffer tank 1110 and the other end connected with the valve 1160. Here, when the buffer tank 1110 is disposed at a side portion of the gas block 1150, and the valve 1160 is disposed at an upper portion of the gas block 1150, the first flow path 1152a may have a shape extending from a side portion to an upper portion of the body 1151. In this case, the first flow path 1152a may have one end exposed to a side surface of the body 1151 and the other end exposed to a top surface of the body 1151.

The second flow path 1152b is defined in the body 1151 so that the second flow path 1152b has one end connected with the valve 1160 and the other end connected with the flow path 1210 of the base 1200. Here, when the valve 1160 is disposed at an upper portion of the gas block 1150, and the base 1200 is disposed at a lower portion of the gas block 1150, the second flow path 1152b may have a shape extending from the upper portion to a lower portion of the body 1151. In this case, the second flow path 1152b may have one end exposed to the top surface of the body 1151 and the other end exposed to a bottom surface of the body 1151.

The valve 1160 controls communication between the first flow path 1152a and the second flow path 1152b of the gas block 1150. Here, the valve 1160 may be operated by inner pressure of the buffer tank 1110, which is measured by the pressure measurement part. For example, the valve 1160 may be a diaphragm valve.

Although not shown, the valve 1160 that is a diaphragm valve will be exemplarily described as below. For example, the valve 1160 may include: a body part having first and second passages, therein, connected to the first and second flow paths 1152a and 1152b of the gas block 1150, respectively; an adjusting part installed in the body part to be moved forward in a direction toward the gas block 1150 or moved backward in a direction opposite to the gas block 1150; a weir installed in the body part to face the adjusting part; and a diaphragm disposed between the adjusting part and the weir and connected to a lower portion of the adjusting part.

The body part may include a first body and a second body, which are separate from and coupled to each other. Also, the diaphragm may be installed between the first body and the second body. Here, an edge of the diaphragm may be disposed between a lower portion of the first body and an upper portion of the second body, and the first body, the diaphragm, and the second body may be coupled to each other. For example, a separate coupling member may pass through the lower portion of the first body, the diaphragm, and the second body, so that the first body, the diaphragm, and the second body are coupled to each other. Thus, an edge of the diaphragm is fixed to the first body and the second body, and the rest of the diaphragm is exposed to an inner space of each of the first body and the second body. Thus, the inner space of the body part may be separated into an upper space and a lower space of the diaphragm by the diaphragm.

The diaphragm may be stretched and contracted. As described above, the edge of the diaphragm is fixed between a lower portion of the first body and an upper portion of the second body, and the rest of the diaphragm is exposed to the inner space of the body part. Here, a top surface of the diaphragm, which is exposed to the inner space of the body part, is coupled or connected to a lower portion of the adjusting part.

Thus, a shape of the diaphragm is deformed according to an operation of the adjusting part, and the diaphragm and the weir contact each other or are separated from each other by the deformation. Here, the adjusting part may be operated by inner pressure of the buffer tank 1110, which is measured by the pressure measurement part.

That is, when the adjusting part is moved forward in a direction toward the weir, the shape of the diaphragm is deformed so that the diaphragm protrudes toward the weir. Here, when a bottom surface of the diaphragm contacts the weir, the first passage and the second passage of the valve 1160 do not communicate with each other. That is, the first passage and the second passage are blocked by the diaphragm or the weir. Thus, the first flow path 1152a and the second flow path 1152b of the gas block 1150 do not communicate with each other. In this case, a gas supplied from the gas supply unit 500 is accommodated in the inner space 1112 of the buffer tank 1110, the first flow path 1152a of the gas block 1150, and the first passage of the valve 1160. That is, a gas discharged from the buffer tank 1110 is introduced to the first passage that is an inner passage of the valve 1160 through the first flow path 1152a of the gas block 1150 as illustrated in FIG. 3. Here, the gas is not introduced to the second passage. Thus, the gas is not discharged to the outside of the gas block 1150 as illustrated in FIG. 3. Also, when a gas is continuously supplied from the gas supply unit 500 to the buffer tank 1110, pressure of each of the inner space 1112 of the buffer tank 1110, the first flow path 1152a of the gas block 1150, and the first passage of the valve 1160 increases.

On the contrary, when the adjusting part is moved backward in a direction opposite to the weir, the shape of the diaphragm is deformed so that the diaphragm protrudes in the direction opposite to the weir. Here, when the bottom surface of the diaphragm is separated and spaced apart from the weir, the first passage and the second passage of the valve 1160 communicate with each other. That is, the first passage and the second passage communicate with each other through a spaced space between the diaphragm and the weir. Thus, the first flow path 1152a and the second flow path 1152b of the gas block 1150 communicate with each other. Thus, the gas passing through the first flow path 1152a of the gas block 1150 passes through the first and second passages of the valve 1160 and then is introduced to the second flow path 1152b of the gas block 1150 again as illustrated in FIG. 4. Thereafter, the gas is introduced to the injection unit 400 through the flow path 1210 of the base 1200, which is connected with the second flow path 1152b.

Here, since each of the inner space 1112 of the buffer tank 1110, the first flow path 1152a of the gas block 1150, and the first passage of the valve 1160 is in a high pressure state, the gas is introduced to the second passage with high pressure. Thus, since the gas is supplied to the injection unit 400 through the second passage, the second flow path 1152b of the gas block 1150, and the flow path 1210 of the base 1200 with high pressure, the gas injected through the injection unit 400 has high pressure. In other words, the gas that is temporarily accommodated in the buffer tank 1110 and then supplied to the injection unit 400 in accordance with another exemplary embodiment may be injected into the chamber 100 with higher pressure than a case when the gas supplied from the gas supply unit 500 is directly supplied to the injection unit 400.

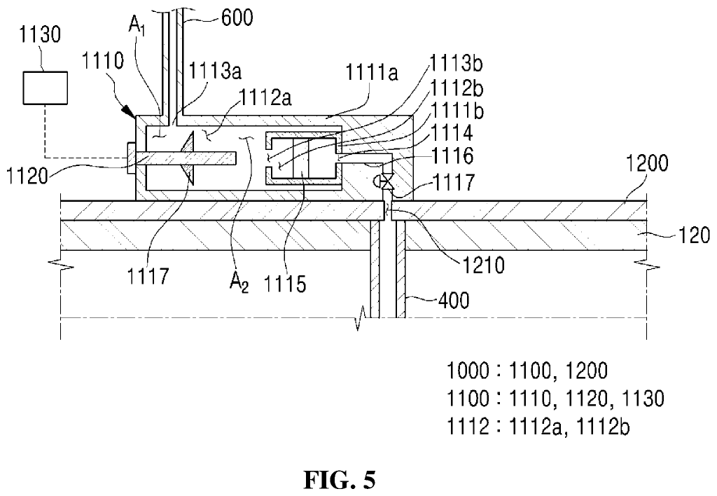

FIG. 5 is a view illustrating a gas supply device in accordance with yet another exemplary embodiment.

A buffer tank 1110 of the gas supply device in accordance with yet another exemplary embodiment may further include a counter-pressure prevention part 1118 disposed in a first space 1112a.

Hereinafter, the buffer tank 1110 in accordance with yet another exemplary embodiment will be described with reference to FIG. 5. Hereinafter, descriptions duplicated with those of an exemplary embodiment will be omitted or simplified.

Referring to FIG. 5, the buffer tank 1110 in accordance with yet another exemplary embodiment may include: a first body 1111a having a first space 1112a capable of accommodating a gas therein; a second body 1111b having a second space 1112b capable of accommodating a gas therein and installed in the first space 1112a of the first body 1111a; a filter 1115 installed in the second space 1112b of the second body 1111b; a discharge pipe 1116 having one end connected to the second body 1111b and the other end connected to an injection unit 400; a buffer valve 1117 installed on the discharge pipe 1116 to control communication with the injection unit 400; and a counter-pressure prevention part 1118 installed in the first space 1112a.

Also, a heater 1120 is installed in the first space 1112a of the first body 1111a like an exemplary embodiment. The counter-pressure prevention part 1118 may be mounted to an outer circumferential surface of the heater 1120 so that the counter-pressure prevention part 1118 is disposed in the first space 1112a as illustrated in FIG. 5. In other words, the counter-pressure prevention part 1118 may be installed on the outer circumferential surface of the heater 1120 to surround the heater 1120 in a circumferential or radial direction. Here, the counter-pressure prevention part 1118 is installed on the heater 1120 so that the counter-pressure prevention part 1118 is disposed at a rear side of a connection pipe 600. More specifically, the counter-pressure prevention part 1118 is mounted to the outer circumferential surface of the heater 1120 so that the counter-pressure prevention part 1118 is disposed at the rear side of the connection pipe 600 in the first space based on a direction in which the gas supplied from the connection pipe 600 flows to an outlet 1114. The feature in which the counter-pressure prevention part 1118 is disposed in the first space 1112a may represent that the counter-pressure prevention part 1118 is disposed at the outside of the second space 1112b.

As described above, the counter-pressure prevention part 1118 is disposed in the first space 1112a and at the rear side of the connection pipe 600. Thus, the first space 1112a of the first body 1111a may include a space (hereinafter, referred to as one side space A₁) disposed at one side of the counter-pressure prevention part 1118 and a space (hereinafter, referred to as the other side space A₂) disposed at the other side of the counter-pressure prevention part 1118. Thus, the counter-pressure prevention part 1118 may be disposed between the one side space A₁ and the other side space A₂ of the first space 1112a.

Also, the connection pipe 600 is connected to the first body 1111a to communicate with the one side space A₁. Also, the counter-pressure prevention part 1118 is adjusted in position so that the other side space A₂ has a size greater than that of the one side space A₁.

As illustrated in FIG. 5, the counter-pressure prevention part 1118 has a shape having an inclined outer circumferential surface. That is, the counter-pressure prevention part 1118 has an inclined surface that gradually close to an inner wall of the first body 1111a in a direction from the one side space A₁ to the other side space A₂. In other words, the counter-pressure prevention part 1118 may have a shape in which an outer diameter gradually increases in the direction from the one side space A₁ to the other side space A₂. Thus, the counter-pressure prevention part 1118 may have the inclined outer circumferential surface.

Also, the outer circumferential surface of the counter-pressure prevention part 1118 is spaced a predetermined distance from the inner wall of the first body 1111a. Thus, a gas introduced into the one side space A₁ may be moved to the other side space A₂ through a space between the counter-pressure prevention part 1118 and the inner wall of the first body 1111a.

The counter-pressure prevention part 1118 may prevent counter-pressure of the gas from the one side space A₁ and the other side space A₂ of the first space 1112a from being generated.

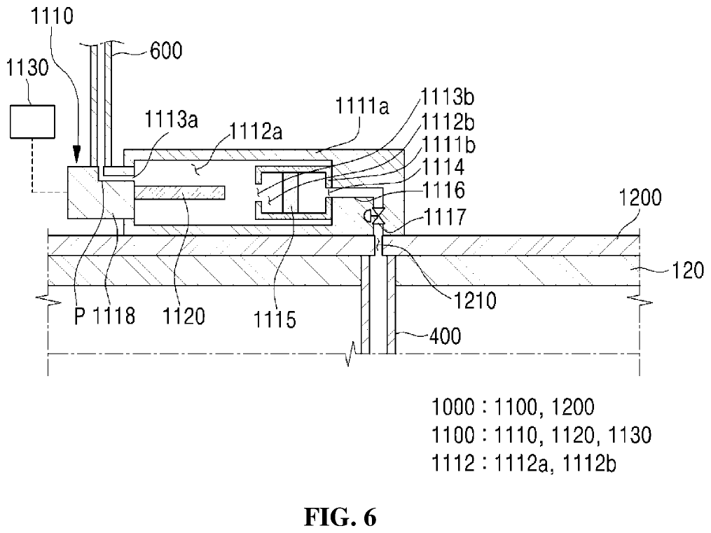

FIG. 6 is a view illustrating a gas supply device in accordance with still another exemplary embodiment.

A buffer tank of a gas supply device 1000 in accordance with still another exemplary embodiment may include a cover 1118 that closes an opening of the buffer tank 1110, through which a heater 1120 passes and has a flow path P therein through which a gas passes.

Hereinafter, the buffer tank 1110 in accordance with still another exemplary embodiment will be described with reference to FIG. 6. Hereinafter, descriptions duplicated with those of an exemplary embodiment will be omitted or simplified.

Referring to FIG. 6, the buffer tank 1110 in accordance with still another exemplary embodiment may include: a first body 1111a having a first space 1112a capable of accommodating a gas therein; a cover 1118 that closes an opening of the first body 1111a and has a passage P through which a gas passes therein; a second body 1111b having a second space 1112b capable of accommodating a gas therein and installed in the first space 1112a of the first body 1111a; a filter 1115 installed in the second space 1112b of the second body 1111b; a discharge pipe 1116 having one end connected to the second body 1111b and the other end connected to an injection unit 400; and a buffer valve 1117 installed on the discharge pipe 1116 to control communication with the injection unit 400.

An opening through which a heater 1120 passes is defined in the first body 1111a. Here, for example, the opening may be defined at a position facing the discharge pipe 1116.

The cover 1118 is a unit of closing the opening defined in the first body 1111a. A portion of the cover 1118 may be inserted to the opening of the first body 1111a, and the rest of the cover 1118 may protrude to the outside of the first body 1111a. Also, the heater 1120 may be connected or mounted to one surface of the cover 1118, which is inserted to the opening of the first body 1111a and exposed to the first space 1112a.

A flow path P through which a gas passes or is moved is defined in the cover 1118. When the buffer tank 1110 includes the cover 1118, a connection pipe 600 is connected to the cover 1118. That is, the connection pipe 600 is installed on the cover 1118 so that the connection pipe 600 communicates with the flow path P defined in the cover 1118. Thus, the flow path P has one end communicating with the connection pipe and the other end communicating with the first space 1112a of the first body 1111a. Thus, a gas supplied to the connection pipe 600 is supplied to the first space 1112a of the first body 1111a through the flow path P defined in the cover 1118.

As described above, in accordance with still another exemplary embodiment, the opening of the first body 1111a is covered by using the cover 1118 in which the flow path is defined, and the connection pipe 600 is connected to the cover 1118. Also, the cover 1118 is connected to the heater 1120. Thus, the heater 1120 and the connection pipe 600 may be separated from the first body 1111a or the buffer tank 1110 by separating the cover 1118 from the first body 1111a. Also, the heater 1120 may be installed in the first space 1112a of the first body 1111a, and the connection pipe 600 may be connected to the buffer tank 1110 by mounting the cover 1118 to the first body. Thus, the heater 1120 and the connection pipe 600 may be easily separated from or installed to the buffer tank 1110 by separating or mounting the cover 1118 from or to the first body 1111a.

In the above-described exemplary embodiments, the filter 1115 is installed in the buffer tank 1110. However, the exemplary embodiment is not limited thereto. For example, the filter 1115 may be provided separately from the buffer tank 1110 and installed at the outside of the buffer tank 1110. Also, the filter 1115 may be disposed between the buffer tank 1110 and the base 1200 or installed to connect the buffer tank 1110 and the base 1200.

As described above, the filter is installed in the buffer tank 1110 or installed to connect the buffer tank 1110 and the base 1200. That is, the filter 1115 in accordance with exemplary embodiments is installed at a position adjacent to the buffer tank 1110.

Hereinafter, an operation of the substrate processing apparatus including the gas supply device in accordance with an exemplary embodiment will be described with reference to FIG. 1. Here, a method for depositing a thin-film on the substrate by the atomic layer deposition (ALD) method will be described as an example.

First, the substrate S is seated on the support 200. Here, the substrate S may be heated to a required process temperature by operating the heater 1120 disposed in the support 200 before or after the substrate S is seated.

Thereafter, a thin-film is deposited on the substrate S by the ALD method. To this end, a source gas, a purge gas, a reactant gas, and a purge gas are sequentially injected into the chamber 100 by using the injection unit 400. That is, ‘injection of the source gas, injection of the purge gas, injection of the reactant gas, and injection of the purge gas’ form a process cycle, and the process cycle is repeated a plurality of times. Also, RF power may be applied to the injection unit 400 by using the RF power unit 700 when the reactant gas is injected. Thus, plasma may be generated in the chamber 100 caused by ionization of the reactant gas.

The source gas injected into the chamber 100 is adsorbed onto the substrate S. Also, as the reactant gas is ionized to generate the plasma, and the ionized reactant gas reacts with the source gas adsorbed onto the substrate S, a thin-film is formed on the substrate S by a reaction between the source gas and the reactant gas. Also, the thin-film having a desired thickness is formed by repeating the above-described process cycle.

Hereinafter, a method for supplying the gas to the injection unit 400 will be described. Here, a method for supplying the purge gas to the injection unit 400 will be described as an example.

The purge gas is supplied to the injection unit 400 by using the third gas supply part 500c in order to supply the purge gas to the injection unit 400. That is, a purge gas of the third storage part 510c is discharged to the third transfer part 520b by opening the valve 1160. Thus, a source gas of the third storage part 510c passes through the third transfer part 520b and the connection pipe and then is supplied to the buffer tank 1110 of the gas supply device 1000. More specifically, the purge gas passing through the third transfer part 520b and the connection pipe 600 is introduced into the inner space 1112 of the buffer tank 1110 through the first inlet 1113a of the buffer tank 1110. In other words, the purge gas is introduced into the first space 1112a of the first body 1111a through the first inlet 1113a defined in the first body 1111a.

Here, the buffer valve 1117 of the buffer tank 1110 is in a closed state. Thus, the purge gas introduced to the buffer tank 1110 remains in the inner space 1112 of the buffer tank 1110 instead of being discharged to the outside. Accordingly, when the purge gas is continuously supplied to the buffer tank 1110 by using the third gas supply part 500c, pressure of the inner space 1112 of the buffer tank 1110 in the closed state gradually increases.

Also, the purge gas may be heated by an operation of the heater 1120 while the purge gas remains in the inner space 1112 of the buffer tank 1110. In other words, the purge gas of the inner space 1112 may be heated by the operation of the heater 1120 so that a temperature of the purge gas does not decrease to be equal to or less than a predetermined temperature. Thus, the purge gas may be prevented from being liquefied although the purge gas remains in the inner space 1112 of the buffer tank 1110 for a predetermined time.

When the pressure of the inner space 1112 of the buffer tank 1110 increases to preset pressure, supply of the purge gas from the third gas supply part 500c is stopped, and the buffer valve 1117 is opened. To this end, a unit for measuring the pressure of the inner space 1112 may be installed in the buffer tank 1110. However, the exemplary embodiment is not limited thereto. For example, a time in which the pressure of the inner space 1112 of the buffer tank 1110 increases to target pressure may be set, and the gas may be supplied from the gas supply unit 500 to the buffer tank 1110 during the set time.

When the buffer valve 1117 is opened, the purge gas of the inner space 1112 of the buffer tank 1110 is discharged to the outside through the discharge pipe 1116. That is, the purge gas in the first space 1112a of the first body 1111a is introduced to the second space 1112b of the second body 1111b, and the purge gas in the second space 1112b is discharged through the discharge pipe 1116. Here, since the pressure of the inner space 1112 of the buffer tank 1110 is high, pressure of the purge gas discharged through the discharge pipe 1116 is high.

Also, the purge gas passing through the discharge pipe 1116 is supplied to the injection unit 400 through the flow path 1210 of the base 1200, which is connected with the discharge pipe 1116. Thereafter, the purge gas is discharged into the chamber 100 through the injection hole 420 defined in the injection unit 400.

Here, since the pressure of the purge gas discharged from the discharge pipe 1116 of the buffer tank 1110 is high, the purge gas discharged from the discharge pipe 1116 is supplied to the flow path 1210 of the base 1200 and the injection unit 400 with high pressure, and the injection pressure of the purge gas injected through the injection unit 400 is high. Thus, the purge efficiency caused by the injection of the purge gas is improved. That is, when the purge gas is injected to purge unreacted gases and by-products in the chamber 100 after the source gas or the reactant gas is injected, the injection pressure of the purge gas may increase, and the purge efficiency of the purge gas may be improved. In other words, purging may be effectively performed by using the same amount of the purge gas.

Although a method for supplying the source gas and the reactant gas of the first and second gas supply parts 500a and 500b to the injection unit 400 through the gas supply device 1000 is not described in detail, the source gas and the reactant gas are supplied to the injection unit 400 by the same method as the above-described method for supplying the purge gas. Thus, the injection pressure of the source gas and the reactant gas injected from the injection unit 400 may increase. Thus, as the amount of each of the source gas and the reactant gas arrived onto the substrate S increases, the deposition rate may be improved.

Also, when the gas is discharged to the outside of the buffer tank 1110, the gas passes through the filter 1115 installed in the buffer tank 1110. Here, the impurities mixed in the gas are filtered by the filter 1115. Thus, the filter 1115 may prevent or suppress impurities from being mixed in the gas injected into the chamber 100. Thus, the substrate or the thin-film may be prevented from being polluted by impurities.

In accordance with the exemplary embodiments, the gas supplied from the gas supply unit may remain in the buffer tank for a predetermined time, and the inner pressure of the buffer tank may increase. Thus, the pressure of the gas discharged from the buffer tank may increase, and accordingly, the injection pressure of the gas injected into the chamber connected with the buffer tank may increase.

The above-described embodiments should be regarded as illustrative rather than restrictive. Accordingly, it should be appreciated that variations to those embodiments can be made by those skilled in the art without departing from the scope of the invention as defined by the following claims.

1-6. (canceled)

7. A gas supply device configured to supply a gas into a chamber in which a substrate is processed, comprising:
a base having a flow path communicating with the inside of the chamber and installed on the chamber; and
a buffer tank having an inner space configured to accommodate a gas and installed on the base to supply a gas to the flow path,
wherein the inner space has a first space and a second space having a volume less than that of the first space and separated from the first space, and
the buffer tank comprises a filter disposed in the second space.

8. The gas supply device of claim 7, wherein the buffer tank comprises:
a first body having a first space therein;
a second body having, therein, a second space having a volume less than that of the first space and disposed in the first space; and
a valve installed between the second space and the chamber.

9. The gas supply device of claim 7, wherein the buffer tank comprises:
a first body having the first space therein;
a second body having, therein, the second space having a volume less than that of the first space and disposed in the first space; and
a discharge pipe connected with the second space,
wherein the gas supply device further comprises a gas block having a first flow path connected with the discharge pipe and a second flow path connected with the flow path of the base and installed on the base.

10. The gas supply device of claim 9, further comprising a valve installed on the gas block to control communication between the first flow path and the second flow path.

11. A gas supply device configured to supply a gas into a chamber in which a substrate is processed, comprising a first body having, therein, a first space configured to accommodate a gas,
wherein a heater is installed in the first space.

12. The gas supply device of claim 11, further comprising:
a second body having a second space having a volume less than that of the first space and installed in the first space; and
a filter installed in the second body so as to be disposed in the second space.

13. The gas supply device of claim 12, wherein a gas block having a first flow path communicating with the second space and a second flow path communicating with the inside of the chamber is connected to the first body.

14. The gas supply device of claim 12, wherein the first body is installed on the second space and a base having a flow path communicating with the inside of the chamber and installed on the chamber.

15. The gas supply device of claim 11, further comprising a cover having one surface connected with the heater, installed on the first body to close an opening of the first body, and having a flow path communicating with the first space therein.

16. The gas supply device of claim 11, further comprising a counter-pressure prevention part installed on the heater to surround the heater in a circumferential direction of the heater,
wherein the first space, which communicates with an inlet through which a gas is introduced, has one side space disposed at one side of the counter-pressure prevention part and the other side space spaced apart relatively to the one side space from the inlet and disposed at the other side of the counter-pressure prevention part.

17. The gas supply device of claim 16, wherein the other side space has a volume greater than that of the one side space.

18. A gas supply device configured to supply a gas into a chamber in which a substrate is processed, comprising:
a base having a flow path communicating with the inside of the chamber and installed on the chamber;
a buffer tank having an inner space configured to accommodate a gas and installed on the base to supply a gas to the flow path; and
a filter connected between the base and the buffer tank.

19. The gas supply device of claim 13, wherein the first body is installed on the second space and a base having a flow path communicating with the inside of the chamber and installed on the chamber.
